(19) United States
(12) Patent Application Publication
(10) Pub. No.: US 2009/0057859 A1
(43) Pub. Date: Mar. 5, 2009

(54) WINDOW-TYPE BALL GRID ARRAY PACKAGE STRUCTURE AND FABRICATING METHOD THEREOF

(75) Inventor: Wei-Kuang Chung, Nantou County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 11/955,355

(22) Filed: Dec. 12, 2007

(30) Foreign Application Priority Data
Aug. 29, 2007 (TW) 96132001

(51) Int. Cl. H01L 23/02

(52) U.S. Cl. 257/680; 257/E23.039

(57) ABSTRACT

A window-type ball grid array (WBGA) package structure includes a substrate, fingers, traces, a solder mask, a die, a window mold compound and solder balls. The substrate has a first surface and a second surface and a window passing there-through. The fingers are on the first surface near the window, and each trace is on the first surface and connected to each finger. Moreover, the traces and a part of the fingers connected thereto are covered by the solder mask. The die is on the second surface and covers the window, and the window is filled by the window mold compound extendedly covering a part of a top surface of the solder mask. Additionally, the solder balls are on the first surface. Due to the foregoing structure, the stress near the fingers may be reduced and thus the lifetime of WBGA package structure may be efficiently increased.

### CROSS-REFERENCE TO RELATED APPLICATION

This application claims the priority benefit of Taiwan application serial no. 96132001, filed on Aug. 29, 2007. The entirety of the above-mentioned patent application is hereby incorporated by reference herein and made a part of this specification.

### BACKGROUND OF THE INVENTION

1. Field of the Invention

The present invention relates to a ball grid array (BGA) package structure and a fabricating method thereof. More particularly, the present invention relates to a window-type BGA (WBGA) package structure and a fabricating method thereof.

2. Description of Related Art

As shown in FIG. 1, a current WBGA package structure includes a substrate 100, a plurality of fingers 102, a plurality of traces 104, a solder mask 106, a window mold compound 108, and solder balls 110. The substrate 110 has a window 112 passing through the upper and lower surfaces of the substrates 110. The position relationship between the die and the substrate 100 is shown in FIG. 2A, and FIG. 2A is a cross-sectional view of FIG. 1 taken along a sectional line II-II.

As known from FIG. 2A, the die 200 is disposed on the lower surface of the substrate 100 and covers the window 112, and the solder mask 106 covers a boundary between the fingers 102 and the traces 104. The window mold compound 108 fills the window 112. In addition, a Ni/Au layer 202 is generally plated on the surface of the fingers 102.

However, in the conventional art, when the structure near the window 112 is tested by the temperature cycling test (TCT), the tensile stress is easily generated among the interface of the window mold compound 108, the solder mask 106, the fingers 102, and the traces 104, as shown in FIG. 2B (FIG. 2B is an enlarged cross-sectional view of Part B in FIG. 2A), and as a result, the traces 104 may be broken.

In addition, the design of the fingers 102 for the substrate 100 used by the current WBGA package structure is as shown in FIG. 3, it is an enlarged top view of Part III in FIG. 1. In FIG. 3, the solder mask 106 covers the boundary between the fingers 102 and the traces 104. However, during the TCT, since each of the traces 104 has a small cross section, only little stress can be implemented on the traces 104. In such a design, due to broken traces 104, package failure often occurs.

### SUMMARY OF THE INVENTION

Accordingly, the present invention is directed to a WBGA package structure, capable of effectively increasing the lifetime of the package structure.

The present invention is also directed to a method of fabricating a WBGA package structure, capable of fabricating a package structure with a longer TCT lifetime.

As embodied and broadly described herein, the present invention provides a WBGA package structure, which includes a substrate, a plurality of fingers, a plurality of traces, a solder mask, a die, a window mold compound, and solder balls. The substrate has a first surface, a second surface, and a window passing through the first surface and the second surface. The fingers are formed on the first surface near the window, and the traces are formed on the first surface and connected to each finger. Moreover, the traces and a part of the fingers connected to the same are covered by the solder mask. The die is disposed on the second surface and covers the window, and the window is filled up by the window mold compound that extendedly covers a part of a top surface of the solder mask. The solder balls are disposed on the first surface.

In an embodiment of the present invention, the fingers include a copper layer and a Ni/Au layer, the Ni/Au layer is located on the copper layer surface without being covered by the solder mask, so as to enhance the welding reliability of welding wires.

In an embodiment of the present invention, the width (W_{f}) of each finger is over 1.5 times larger than the line width (Wₜ) of each trace.

In an embodiment of the present invention, the die further includes at least one pad located on a die surface facing the window.

In an embodiment of the present invention, the trace is made of copper.

In an embodiment of the present invention, the solder balls are electrically connected to the fingers by the traces.

In an embodiment of the present invention, the solder balls are made of copper, tin, lead, or any alloy thereof.

In an embodiment of the present invention, the package structure further includes an adhesion layer located between the die and the substrate, so as to closely adhere the die on the substrate.

The present invention further provides a method of fabricating a WBGA package structure, which includes the following steps. Firstly, a substrate is provided, which has a first surface, a second surface, and a window passing through the first surface and the second surface. Next, a conductive layer is formed on the first surface, which includes a plurality of traces and a plurality of fingers, and the fingers are formed near the window. Then, a solder mask is formed on the conductive layer, so as to expose a part of the fingers, and then a plurality of solder balls is formed on the first surface. Then, a die is provided on the second surface to cover the window, and the window is filled up with a window mold compound that extendedly covers a part of a top surface of the solder mask.

In another embodiment of the present invention, the process of filling up the window with the window mold compound includes the following steps. Firstly, a mold is provided, which has a sprue and a mold cavity, in which the sprue is connected to the mold cavity. Next, the mold is sealed and closely clamped to make the window of the substrate be located in the mold cavity, and then a plastic mold compound is injected into the mold cavity. After that, the plastic mold compound is cured, and the mold is opened.

In another embodiment of the present invention, the process of forming the solder mask on the conductive layer includes: firstly, coating a solder resist on the first surface; then, performing a photolithographic process on the solder resist, and finally removing a part of the solder resist.

In another embodiment of the present invention, the method further includes forming a Ni/Au layer on a part of an exposed surface of the fingers, after the solder mask is formed on the conductive layer. The process of forming the Ni/Au layer includes a plating process.

In another embodiment of the present invention, the method further includes forming an adhesion layer on the second surface before the die is provided on the second surface.

In another embodiment of the present invention, the conductive layer includes a copper layer.

In the present invention, the structure with the solder mask covering a part of the fingers is adopted, together with the design that the window mold compound extendedly covers a part of the top surface of the solder mask, so that not only the tensile stress capable of being borne by the trace is enhanced, but the inherent stress distribution between the solder mask and the window mold compound can also be changed. Therefore, the present invention can effectively increase the TCT lifetime of the WBGA package structure.

In order to make the aforementioned and other objects, features and advantages of the present invention comprehensible, embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a conventional WBGA package structure.

FIG. 2A is a cross-sectional view of FIG. 1, taken along a sectional line II-II.

FIG. 2B is an enlarged cross-sectional view of Part B in FIG. 2A.

FIG. 3 is an enlarged top view of Part III in FIG. 1.

FIG. 4 is a top view of a WBGA package structure according to a first embodiment of the present invention.

FIG. 5A is a cross-sectional view of FIG. 4, taken along a sectional line V-V

FIG. 5B is an enlarged cross-sectional view of Part B in FIG. 5A.

FIG. 6 is an enlarged top view of Part VI in FIG. 4.

FIG. 7 is flow chart of a process for fabricating a WBGA package structure according to a second embodiment of the present invention.

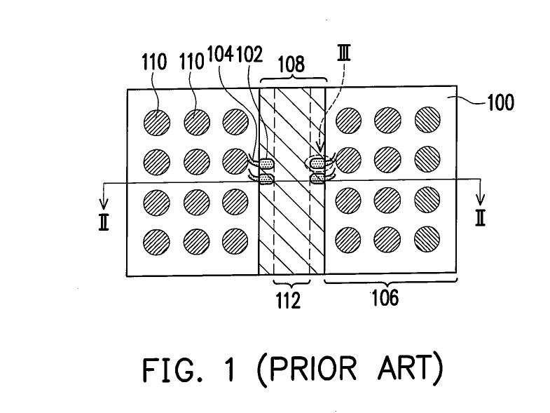

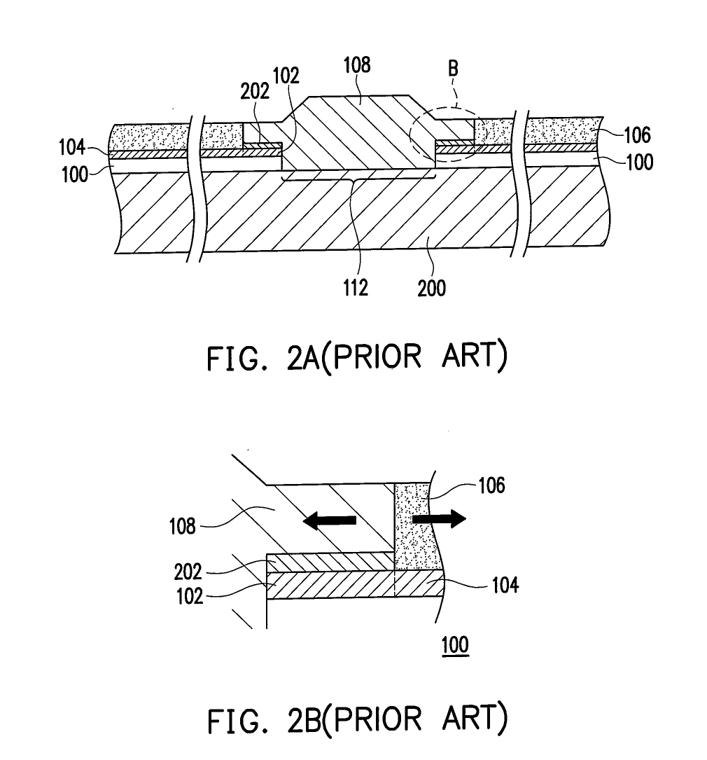

### DESCRIPTION OF EMBODIMENTS

The present invention is described below in detail with reference to the accompanying drawings, and the embodiments of the present invention are shown in the accompanying drawings. However, the present invention can also be implemented in a plurality of different forms, so it should not be interpreted as being limited in the following embodiments. Actually, the following embodiments are intended to demonstrate and illustrate the present invention in a more detailed and completed way, and to fully convey the scope of the present invention to those of ordinary skill in the art. In the accompanying drawings, in order to be specific, the size and relative size of each layer and each region may be exaggeratedly depicted.

It should be known that although “first”, “second” and the like are used in the present invention to describe each element, region, layer, and/or part, such words are not intended to restrict the element, the region, the layer, and/or the part, but shall be considered to distinguish one element, region, layer, or part from another. Therefore, under the circumstance of without departing from the teaching of the present invention, the first element, region, layer, or part can also be called the second element, region, layer, or part.

In addition, “under”, “on”, and similar words for indicating the relative space position are used in the present invention to illustrate the relationship between a certain element or feature and another element or feature in the drawings. It should be known that, beside those relative space words for indicating the directions depicted in the drawings, if the element in the drawing is inverted, the element described as “under” another element or feature becomes “on” another element or feature.

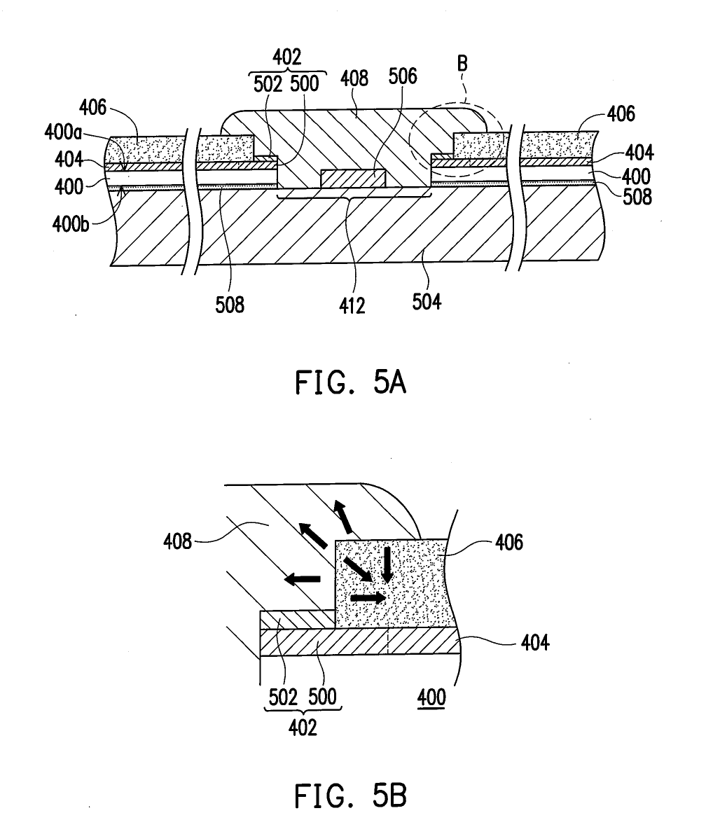

FIG. 4 is a top view of a WBGA package structure according to a first embodiment of the present invention. FIG. 5A is a cross-sectional view of FIG. 4 taken along a sectional line V-V.

Referring to FIGS. 4 and 5A, the WBGA package structure of the first embodiment includes a substrate 400, a plurality of fingers 402, a plurality of traces 404, a solder mask 406, a window mold compound 408, and solder balls 410. The substrate 400 has a first surface 400a, a second surface 400b, and a window 412 passing through the first surface 400a and the second surface 400b. The fingers 402 are formed on the first surface 400a near the window 412, and the traces 404 are formed on the first surface 400a and connected to the fingers 402, in which each finger 402 includes, for example, a copper layer 500 and a Ni/Au layer 502, and the trace 404 is made of, for example, copper. The Ni/Au layer 502 is located on the surface of the copper layer 500 without being covered by the solder mask 406, so as to enhance the welding reliability of welding wires. The width (W_{f}) of the finger 402 is over 1.5 times larger than the line width (Wₜ) of the trace 404. In addition, although only several fingers 402 and traces 404 are shown in the drawing, those of ordinary skill in the art can change the number of the fingers 402 and the traces 404 according to the circuit wiring design.

Referring to FIGS. 4 and 5A, the traces 404 and a part of the fingers 402 connected to the traces 404 are covered by the solder mask 406. A die 504 is securely attached to the second surface 400b, for covering the window 412. In addition, the surface of the die 504 facing the window 412 includes at least one pad 506 for electrically connecting to the substrate 400. The window mold compound 408 fills the window 412 and extendedly covers a part of the top surface of the solder mask 406. The solder balls 410 are disposed on the first surface 400a and electrically connected to the fingers 402 via the traces 404. The solder balls 410 can be made of, for example, copper, tin, lead, or any alloy thereof. In addition, in the first embodiment, an adhesion layer 508 is further added between the die 504 and the substrate 400, so as to closely adhere the die 504 on the substrate 400.

The window mold compound 408 for the WBGA package structure in the first embodiment extendedly covers a part of the top surface of the solder mask 406, as shown in FIG. 5B, it is a cross-sectional view of Part B in FIG. 5A. Therefore, the stress distribution between the solder mask 406 and the window mold compound 408 occurs as indicated by the arrows in FIG. 5B, which effectively increases the TCT lifetime of the WBGA package structure.

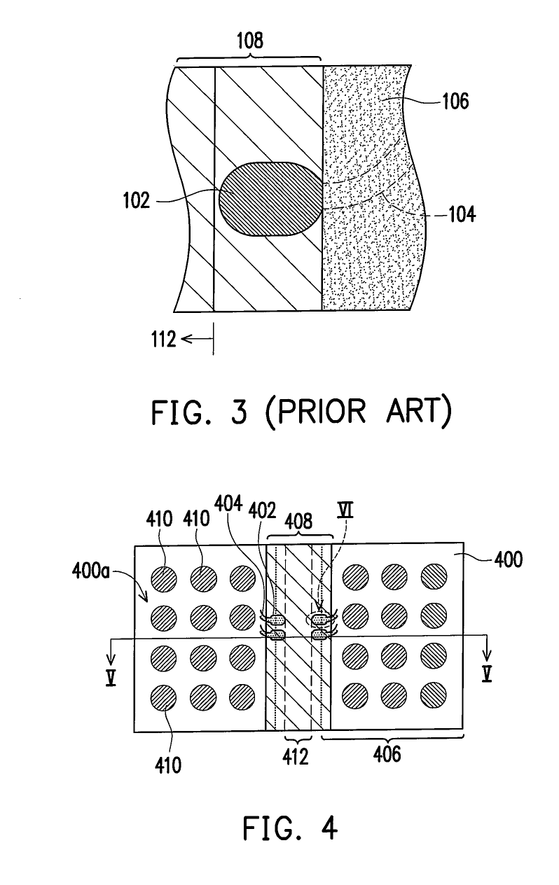

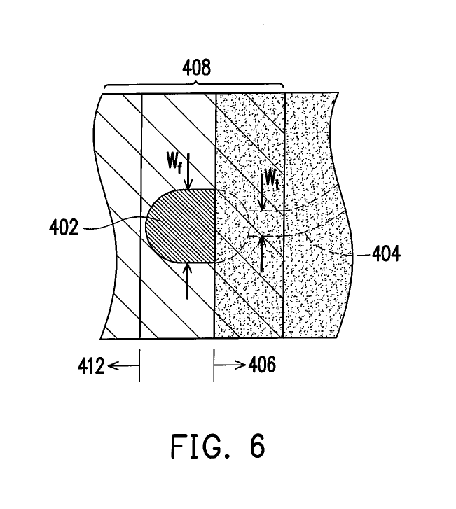

Furthermore, the solder mask 406 of the WBGA package structure in the first embodiment covers a part of the fingers 402, as shown in FIG. 6, and herein FIG. 6 is an enlarged top view of Part VI in FIG. 4. The width (W_{f}) of the finger 402 is, for example, over 1.5 times larger than the line width (Wₜ) of the trace 404. Therefore, compared with the conventional structure (shown in FIG. 3), as the increasing of the cross sectional area at the boundary between the solder mask 406 and the finger 402, the original tensile stress capable of being borne by the trace 404 can be enhanced, so as to increase the TCT lifetime of the WBGA package structure.

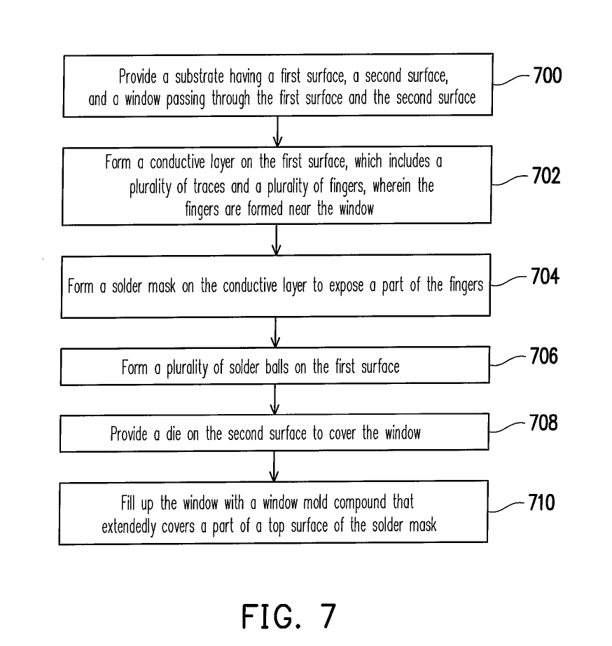

FIG. 7 is a flow chart of a process for fabricating a WBGA package structure according to a second embodiment of the present invention.

Referring to FIG. 7, the second embodiment mainly focuses on the method of fabricating the modified structure of the present invention. Firstly, in Step 700, a substrate is provided, which has a first surface, a second surface, and further has a window passing through the first surface and the second surface.

Next, in Step 702, a conductive layer is formed on the first surface, which includes a plurality of traces and a plurality of fingers, and the fingers are formed near the window. The conductive layer is, for example, a copper layer.

Next, in Step 704, a solder mask is formed on the conductive layer, so as to expose a part of the fingers. The process of forming the solder mask on the conductive layer includes the following steps, for example, firstly coating a solder resist on the first surface; then performing a photolithographic process on the solder resist; and finally removing a part of the solder resist. In addition, after the solder mask is formed, a Ni/Au layer can be formed on a part of the exposed surface of the fingers, in which the process of forming the Ni/Au layer is, for example, a plating process.

Then, in Step 706, a plurality of solder balls is formed on the first surface. The solder balls can be fabricated according to the technique in the conventional art, which thus will not be repeatedly described herein.

Then, in Step 708, a die is provided on the second surface to cover the window. Before the die is provided on the second surface, an adhesion layer is firstly formed on the second surface, which is helpful for enhancing the subsequent adhesion property between the die and the substrate.

Then, in Step 710, the window is filled up with the window mold compound that extendedly covers a part of the top surface of the solder mask. The process of filling up the window with the window mold compound can be achieved through the technique in the conventional art. For example, firstly, a mold having a sprue and a mold cavity is provided, in which the sprue is connected to the mold cavity. Next, the mold is sealed and closely clamped, so as to make the window of the substrate be located in the mold cavity, and then the plastic mold compound is injected into the mold cavity. After that, the plastic mold compound is cured, and then the mold is opened.

To sum up, the efficacy of the present invention lies in that, the window mold compound extendedly covers a part of the top surface of the solder mask, such that the stress between the solder mask and the window mold compound is dispersed, and thus effectively increasing the TCT lifetime of the WBGA package structure. In addition, the solder mask for the WBGA package structure of the present invention covers a part of the fingers, so as to enlarge the cross sectional area of the boundary between the solder mask and the fingers, and to enhance the tensile stress capable of being borne by the traces, and thus, the TCT lifetime of the of the WBGA package structure is further increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A window-type ball grid array (WBGA) package structure, comprising:
a substrate, having a first surface, a second surface, and a window passing through the first surface and the second surface;
a plurality of fingers, formed on the first surface near the window;
a plurality of traces, formed on the first surface and electrically and respectively connected to a corresponding one of the fingers;
a solder mask, covering the traces and a part of the fingers connected to the traces;
a die, securely attached to the second surface and covering the window;
a window mold compound, filling the window and extendedly covering a part of a top surface of the solder mask; and
a plurality of solder balls, disposed on the first surface.

2. The WBGA package structure as claimed in claim 1, wherein each finger comprises:
a copper layer; and
a Ni/Au layer, located on the copper layer surface without being covered by the solder mask.

3. The WBGA package structure as claimed in claim 1, wherein a width (W_{f}) of each finger is over 1.5 times larger than a line width (Wₜ) of each trace.

4. The WBGA package structure as claimed in claim 3, wherein the die further comprises a pad located on a surface facing the window.

5. The WBGA package structure as claimed in claim 1, wherein the trace is made of copper.

6. The VVBGA package structure as claimed in claim 4, wherein the solder balls are electrically connected to the fingers by the traces.

7. The WBGA package structure as claimed in claim 1, wherein the solder balls are made of copper, tin, lead, or any alloy thereof.

8. The WBGA package structure as claimed in claim 3, further comprising an adhesion layer located between the die and the substrate.
